(19) United States
(12) Patent Application Publication
(10) Pub. No.: US 2006/0042678 A1
(43) Pub. Date: Mar. 2, 2006

(54) Photoelectric cell

(76) Inventors: Dewen Dong, Hull (GB); Stephen M. Kelly, Beverley (GB); Mary O'Neill, Hull (GB)

Correspondence Address: Thomas Q Henry;Woodard Emhardt Moriarty McNett & Henry, 3700 Bank One Center Tower, Indianapolis, MN, 46204, US

(21) Appl. No.: 10/519,443

(22) PCT Filed: Jul. 1, 2003
(86) PCT No.: PCT/GB03/02830

§ 371 Date: Dec. 29, 2004

(30) Foreign Application Priority Data
Jul. 1, 2002 (GB) 0215150.4

(51) Int. Cl. H01L 25/00

(52) U.S. Cl. 136/244; 136/252

(57) ABSTRACT

A photoelectric cell comprising first and second electrodes, a plurality of nanowires which extend between the electrodes, an a structure disposed between the nanowires.

The present invention relates to a photoelectric cell.

Photovoltaic cells and photoconductive cells are both types of photoelectric cell. The photovoltaic effect is widely employed, for example in electro-optical switches, photodetectors, solar cells and photodiodes. Most commercial photovoltaic devices comprise inorganic semiconductors, since these are easy to fabricate as highly ordered crystals and provide relatively high (quantum) efficiency of conversion of light (photons) into electric current (holes and electrons) as well as a photovoltage. However, it remains expensive to produce large amounts of electricity using photovoltaic devices, for example solar cells.

Photovoltaic devices utilising organic materials would offer the potential advantages of large surface area, mechanical flexibility and ruggedness, ease of processing (e.g., absence of high-temperature and high-vacuum processes) and, in some cases, lithographic patternability and, potentially, significantly lower cost. There has been considerable work in this field. It has been found that photovoltaic devices fabricated using a single layer of an organic polymer between two transparent electrodes exhibit low quantum efficiency¹⁻⁴.

It has been found⁵⁻⁷ that exciton disassociation in devices containing two different conjugated polymers is enhanced at the interface between the two polymers, if the electron affinities of the polymers are not identical. This is because it is energetically favourable for the hole to transfer into the material with the lower ionisation potential, leaving the electron on the material with the higher electron affinity. Unfortunately, the quantum efficiency of bilayer polymer devices has been found to be low. This is because phase separation prohibits efficient polymer mixing, thus limiting the size of the interface between polymers, and limiting the diffusion length of singlet excitons in the conjugated polymers⁶ (e.g., 5-15 nm).

In an attempt to increase the efficiency of organic polymer based photovoltaic devices, composite materials have been used. These materials attempt to combine the photovoltaic and electronic properties of inorganic semiconductors with the large-area processability, flexibility and robustness of organic polymers. Composite materials appear to have advantages, provided the interfacial area can be made large. Composite materials with different electron affinities are required in order to give effective charge separation, and must provide efficient charge transport to the electrodes without allowing significant amounts of recombination to occur (recombination of the electrons and holes causes a direct reduction of the power yielded by the photovoltaic device).

Nanocrystals made from II-VI semiconductor materials appear to be highly suited to use as part of a composite material. This is because their very small size means that they present a very high proportion of material at their surfaces (60% for a 2 nm nanosphere). In addition II-VI semiconductors are excellent electron conductors. Many II-VI inorganic semiconductor materials exhibit a high electron affinity, e.g., CdSe. The term ‘nanocrystal’ is intended in this context to refer to particles of material with a size that is comparable to the size of excitons in bulk materials, i.e. typically 4 to 10 nm.

The wave function of the exciton generated in the bulk of a semiconductor nanocrystal will almost certainly reach the nanocrystal surface. Nanocrystals exhibit optical and electrical properties that are very different from those of bulk semiconductors made from the same materials. These properties can be conveniently modified by simple alteration of their size. Most notably, the effective band-edge of the semiconductor can be tuned to higher energies by decreasing the nanocrystal size through the effect of quantum confinement of the electronic wavefunctions. For this reason bilayer nanocrystal/polymer composites incorporating inorganic nanocrystals and organic polymers have been investigated recently⁸ as large-area, thin-film photovoltaic devices (e.g., CdS and CdSe dispersed in polyphenylvinylene [PPV] polymers⁹). Significantly higher quantum efficiencies (≈12%) were obtained compared with those reported for purely organic polymer devices.

Several remaining problems are associated with photovoltaic devices constructed using composites of organic and inorganic material: Recombination of holes and electrons occurs since they pass through the same material in order to reach the electrodes. Non-passivated nanocrystals tend to aggregate, resulting in lower efficiencies of charge separation of singlet excitons. Phase separation between nanocrystals and the polymer matrix occurs. Carrier loss occurs due to charge trapping at dead ends in the nanocrystal network.

It is an object of the present invention to provide a photoelectric cell which overcomes or substantially mitigates at least one of the above disadvantages.

According to a first aspect of the invention there is provided a photoelectric cell comprising first and second electrodes, a plurality of nanowires which extend between the electrodes, and a structure disposed between the nanowires.

The term ‘nanowire’ is intended to mean that the diameter of the nanowires is sufficiently small that quantum mechanical effects arise in the nanowires.

Preferably, the structure is a columnar structure.

Preferably, the structure comprises tubes each of which are located around a respective nanowire.

Preferably, the tubes extend between the electrodes.

Preferably, the structure comprises organic polymer material.

Preferably, the organic polymer material comprises a cross-linked organic compound which may be a polyaromatic compound. The organic polymer material is preferably in a liquid crystalline phase which may be a columnar liquid crystalline phase.

Preferably, the nanowires are fabricated from inorganic material.

Preferably, the nanowires are fabricated from inorganic semiconductor material. These are preferably II-IV and II-VI inorganic nanocrystals. Preferably, the nanocrystals have a high electron affinity and preferably an ionisation potential that is higher than that of the surrounding inorganic material.

Preferably the inorganic material comprises transition metal ions which may be selected from the group consisting of cadmium and zinc. The inorganic material preferably comprises an anionic species which may be selected from the group consisting of sulfur, selenium and tellurium.

Preferably, the nanowires are less than 20 nanometres in diameter. Most preferably, the nanowires are less than 10 nanometres in diameter.

According to a second aspect of the invention there is provided a method of fabricating a photoelectric cell comprising the steps: formation of nanowires within a templating agent; and placement of the nanowires between first and second electrodes so that the nanowires extend between the electrodes.

Preferably the templating agent is formed by a method comprising the steps: dissolution of a salt of an organic compound in a solvent under conditions suitable for self-organisation of the organic compound to form a gel containing nanotubes; and polymerisation of the nanotubes to form polymeric nanotubes. The nanotubes are preferably photochemically polymerised.

Preferably the nanowires are formed by treatment of the gel with an anion source which may be selected from the group consisting of hydrogen sulfide, hydrogen selenide and hydrogen telluride.

The photoelectric cell may be a photovoltaic cell or a photoconductive cell.

A specific embodiment of the invention will now be described with reference to the accompanying figures, in which

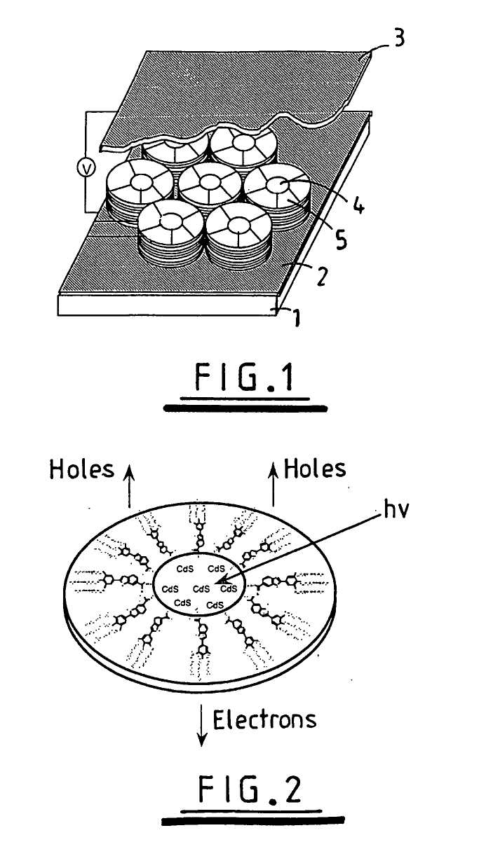

FIG. 1 is a schematic illustration of a photoelectric cell which embodies the invention;

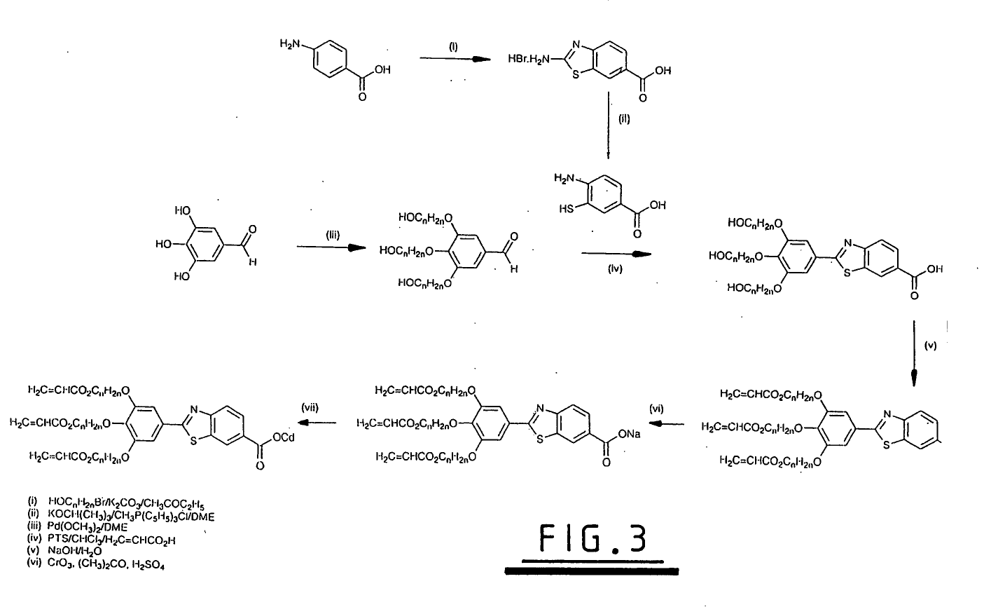

FIG. 2 is a schematic illustration of a nanowire and polymer tube structure which forms part of the photoelectric cell shown in FIG. 1;

FIG. 3 is a schematic diagram which illustrates synthesis of the structure;

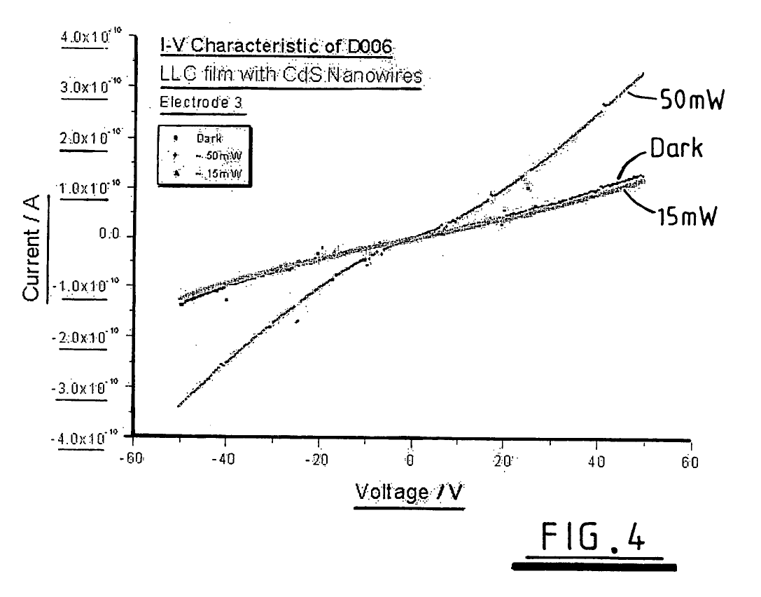

FIG. 4 is a graph of current-voltage characteristics for an embodiment of the present invention.

Referring to FIG. 1, a photovoltaic cell which embodies the invention comprises a glass substrate 1, a first transparent Indium Tin Oxide (ITO) electrode 2 and a second transparent ITO electrode 3 spaced apart from the first electrode 2 and substantially parallel therewith. An array of semiconductor nanowires 4 extends between the electrodes 2, 3. For ease of illustration the nanowires 4 are shown in FIG. 1 as not extending fully between the electrodes 2, 3. Each nanowire 4 is surrounded by a tube 5 of polymer. Each tube 5 of polymer extends fully between the electrodes 2, 3. For ease of illustration the tubes 5 are shown in FIG. 1 as not extending fully between the electrodes 2, 3.

The nanowires 4 are fabricated from cadmium sulfide (CdS), but may be fabricated from any suitable inorganic semiconductor material (e.g. CdS, CdSe, ZnS or ZnSe). The polymer which forms the tubes 5 is a highly cross-linked polymer film of organic, columnar-liquid-crystal material. The polymerised columnar liquid-crystalline state generates and maintains architectural control of the nanocomposite (i.e. the nanowires 4 and the tubes 5) as well as passivating and preventing agglomeration of the nanowires 4.

The nanowire 4 and polymer tube 5 structure provides a very large-area interface between the inorganic semiconductor (CdS) and the organic polymer. This large-area interface ensures that an exciton, formed when photons having an appropriate energy are incident upon the structure (an incident photon is shown schematically in FIG. 2), diffuses to the interface to allow charge separation before radiative recombination. Following exciton generation, charge separation of the electron and hole which comprise the exciton occurs, and the hole and the electron are transported towards opposite electrodes.

Holes and electrons follow two distinct charge transport pathways; the electrons are transported in the semiconductor nanowires 4, and the holes are transported in the organic polymer tubes 5 (this is shown schematically in FIG. 2). The direction of charge propagation is orthogonal to the surfaces of the electrodes 2, 3 and this allows the holes and electrons to propagate to the electrodes (under a bias voltage). The confinement of the electrons in the nanowires 4, together with the fact that the separation of the nanowires 4 is much greater than the wavefunction of the electrons, prevents transport of the electrons from the nanowires 4 to the organic polymer tubes 5. The carrier transport is almost entirely anisotropic, and in the desired direction towards the electrodes 2, 3. Since the holes and electrons propagate along different pathways, recombination of the holes and electrons is minimised. This is advantageous because it maximises the transport of the electrons and holes to the electrodes 2, 3.

Absorption of incident photons, and exciton generation, occurs both in the nanowire 4, as shown schematically in FIG. 2, and the polymer. The wavelength at which photon absorption (and exciton generation) occurs is dependent upon the semiconductor material used to fabricate the nanowires, the diameter of the nanowires, and the polymer absorption edge. It has been found that suitable combinations of materials and dimensions will lead to photon absorption at wavelengths across the near UV, visible and near IR spectrum.

In one embodiment of the invention, nanowires of 20 nanometres in diameter are formed from CdSe. The band gap of CdSe is 1.8 eV, which leads to photon absorption at wavelengths of 689 nanometres or less. If nanowires of less than 20 nanometres diameter are chosen, for example nanowires of 10 nanometres diameter or less, the band gap of CdSe will be increased, and the photon absorption wavelength correspondingly decreased.

The inorganic semiconductor used to fabricate the nanowires preferably comprises II-VI and III-V inorganic nanocrystals with an ionisation potential that is higher than that of the surrounding inorganic material.

A photoelectric cell which embodies the invention is fabricated as follows:

A photochemically polymerisable (crosslinkable) organic compound is prepared and subsequently converted to an appropriate transition metal salt by treatment with a source of transition metal ions, for example, cadmium chloride. Any transition metal ion may be used, however it is likely that cadmium and zinc will be the most suitable, since II-VI semiconductors, such as CdS, CdSe, ZnS or ZnSe, are known to be very efficient photovoltaic and electron transport materials.

The transition metal salt of the organic compound is then mixed with a suitable solvent, such as water, and a photoinitiator, for example, 2-hydroxy-2-methylpropiophenone, Irgacurore or AIBN. Subsequent self-organisation of the salt of the organic compound within the solvent forms a lyotropic liquid crystalline gel containing nanotubes approximately 4-10 nm in diameter.

The self-organised gel is transferred to a suitable electrode, for example ITO covered glass, heated into an isotropic liquid state, compressed into a thin film using a suitable substrate, such as quartz, and finally allowed to cool to room temperature. The gel thus forms a uniform thin film of an inverse hexagonal mesophase with nanotube channels aligned perpendicular to the electrode surfaces.

The transition metal salt of the organic compound within the film is then photochemically polymerised by illumination with ultra violet light (λ=320-365 nm) to form a resilient three-dimensional organic templating agent containing polymeric nanotubes and transition metal ions available for further reaction.

The upper quartz substrate is then removed and the film treated with a suitable anion source, such as a chalogenide gas (i.e. H₂S, H₂Se or H₂Te) to convert the cores of the polymeric nanotubes containing the available transition metal ions into electron-transporting semiconductor nanowires formed of, for example, CdS, CdSe, ZnS or ZnSe.

The resultant nanocomposite is then dried and a metallic contact, for example aluminium, deposited over the structure.

The diameter of the nanowires produced depends upon the amount of solvent present within the gel and the supramolecular structure of the liquid crystal, which in turn, depends upon the chemical structure of the organic compound. Nanowires with concentric layers of different compounds, for example CdSe and CdS, can be produced by sequential treatment of the film with different anion sources such as H₂Se and H₂S.

Experimental details of the synthesis of a specific, non-limiting, embodiment of the present invention will now be described.

Synthesis of 3,4,5-tris(11′-hydroxyundecyloxy)benzaldehyde:

3,4,5-trihydroxybenzaldehyde (4.114 g, 26.7 mmol) was dissolved in 200 ml DMF (dried with molecular sieves 3A for 3 days) in a 250 ml three-necked round-bottomed flask equipped with nitrogen inlet and a magnetic stirrer. To this solution was then added K₂CO₃ (36.9 g, 267 mmol). The resulting heterogeneous mixture was placed in a 110° C. oil bath and stirred vigorously for half an hour. The suspension then became orange. 11-Bromoundecan-1-ol (22.16 g, 88 mmol) was then added slowly under a light nitrogen flush. The reaction was stirred at this temperature for a further 20 h. The resulting brown suspension was cooled to ambient temperature, and the supernatant separated from the precipitate by filtration. After removal of the solvent from the filtrate using a rotary evaporator at 80° C., the residue was dissolved in 150 ml of HCl (1.0M), then extracted with ethyl acetate three times. The combined organic phase was washed with water and dried over Na₂SO₄. After removal of organic solvent, the organic solution gave a pale solid. Recrystallization from ethyl acetate afforded a pale needle crystal product 14.3 g (80.8%), mp: 82-84° C.

Synthesis of 2-amino-4-carboxybenzothiazole hydrobromide:

4-Aminobenzoic acid (27.4 g, 0.2 mol) and ammonium thiocyanate (30.4 g, 0.4 mol) were dissolved in 200 ml of acetic acid in a 500 ml three-necked flask cooled in an ice bath. A solution of bromine (10.5 ml, 32 g, 0.2 mol) in 50 ml acetic acid was added slowly under stirring. External cooling was applied throughout the process to keep the temperature below 10 C and stirring was continued for 2 h after all bromine was added. The precipitate of 1-imino-4-carboxybenzthiazole hydrobromide was removed by filtration at the pump. The yellow solid was washed with acetic acid twice to afford 38 g crude product (yield 68.7%). The melting point of the compound was not detectable for decomposition over 350° C.

Synthesis of 3-mercapto-4-amino-benzoic acid:

2-Amino-4-carboxybenzthiazole (27.5 g, 0.1 mol) was added to a solution of potassium hydroxide (112 g, 2 mol) in methanol (100 ml) and water (100 ml). The mixture was stirred and heated to reflux. Ammnoia gas was evolved and a solution was formed one hour later. The solution was refluxed for 20 h. After cooling to room temperature, the solution was poured into 500 ml acetic acid (5N). A green solid was precipitated from the solution. The melting point of the compound was not detectable for decomposition over 350° C.

Synthesis of 2[3,4,5-tris(11′-hydroxyundecyloxy)phenyl]-5-carboxybenzothiazole:

3,4,5-tris(11′-hydroxyundecyloxy)benzaldehyde (6.64 g, 0.01 mol) and 3-mercapto-4-amino-benzoic acid (1.69 g, 0.01 mol) were added to a 250 ml three-necked round-bottom flask containing 50 ml DMSO. The mixture was stirred under N₂ to form a solution, then heated to 130° C. for 20 h. The mixture was poured into 50 ml water then extracted with THF three times. The combined organic phase was dried over Na₂SO₄. After being concentrated, the residue was isolated with use of a column to afford 3.4 g white solid. Melting point is: 100-102° C.

Synthesis of 2[3,4,5-tris(11′-acryloyloxyundecyloxy)phenyl]-5-carboxybenzothiazole:

2[3,4,5-tris(11′-hydroxyundecyloxy)phenyl]-5-carboxybenzothiazole (1.58 g, 1.92 mmol) was dissolved in dry THF (30 ml) in a 100 ml three-necked round-bottomed flask equipped with nitrogen inlet and a magnetic stirrer. To this solution was then added N,N′-dimethylaniline (0.73 g, 6.0 mmol) and 2,6-di-tert-butyl-4-methylphenol (BHT, 2 mg). This mixture was kept at 0° C. in the absence of light while acryloyl chloride (0.54 g, 48.5 mmol) was added slowly dropwise. The mixture was then stirred in the absence of light at ambient temperature for 18 h. After the reaction was complete, methanol (1 ml) was added and the solution was poured into 1.5M HCl solution (150 ml). The solution was extracted with ethyl acetate three times. The combined organic phase was dried over anhydrous Na₂SO₄ and concentrated under vacuum to afford a pale residue. The crude product was isolated with use of a column to afford an off-white sticky substance (1.53 g yield: 82.1%).

Synthesis of sodium 2[3,4,5-tris(11′-acryloyloxyundecyloxy)phenyl]-5-carboxybenzothiazole:

2[3,4,5-tris(11′-acryloyloxyundecyloxy)phenyl]-5-carboxybenzothiazole (0.59 g, 6 mmol) was dissolved in methanol (75 ml) and acetone (75 ml) in a 250 ml single-necked round-bottomed flask with a magnetic stirrer. To this suspension was added slowly 2.4 ml 0.52M NaOH as a methanol solution. After the addition, a homogeneous solution was formed, then the solution was further stirred for 1 h in the absence of light. Then the solvent was removed in vacuo to yield a tacky white solid.

Synthesis of cadmium 2[3,4,5-tris(11′-acryloyloxyundecyloxy)phenyl]-5-carboxybenzothiazole:

In a 250 ml Erlenmeyer flask, cadmium chloride (68 mg, 0.29 mmol) was dissolved in ethanol (10 ml) and water (10 ml). An ethanolic solution of sodium 2[3,4,5-tris(11′-acryloyloxyundecyloxy)phenyl]-5-carboxybenzothiazole (0.58 mmol) was added slowly dropwise with vigorous stirring into the cadmium chloride solution. As the addition proceeded, the solution became cloudy. The mixture was stirred under nitrogen in the absence of light for 5 h. The mixture was washed with a saturated aqueous NaCl solution and then deionized water and dried over anhydrous sodium sulfate. The solvents were removed in vacuo, yielding a pale yellow solid.

Preparation of lytropic liquid crystalline inverse hexagonal phase of cadmium 2[3,4,5-tris(11′-acryloyloxyundecyloxy)phenyl]-5-carboxybenzothiazole:

The inverse hexagonal phase was made by mixing 80/10/10 (w/w/w) of cadmium 2[3,4,5-tris(11′-acryloyloxyundecyloxy)phenyl]-5-carboxybenzothiazole/distilled water/p-xylene in a tapered 40 ml centrifuged tube under a nitrogen atmosphere. The resulting mixture was sealed and centrifuged at 2800 rpm for 15 min, hand-mixed with a spatula, and then placed in an ultrasonic bath for 15 min. This procedure was repeated once. After this, the resulting pale paste was allowed to equilibrate under a static nitrogen atmosphere for 12 h at ambient temperature in absence of light. The product obtained was then characterised by means of polarised light microscopy and low angle X-ray diffraction.

Preparation of Cd-LLC polymer:

A small ball of the equilibrated LLC phase was placed on glass microscope slide and lightly covered with another one. The lightly sandwiched sample was then placed momentarily in an oven and heated to 90° C. As soon as the LLC sample began to melt into a transparent isotropic fluid, it was quickly removed from the heat and the slides were pressed together to force the fluid into a thin film. The sample was subsequently allowed to cool to ambient temperature and then exposed to UV light (365 nm) or laser under a nitrogen atmosphere for 1 h. Separating the slides and detaching the film with a needle tip afforded a transparent, flexible, free-standing film.

Preparation of CdS-LLC Polymer:

The thin-film sample of Cadmium-LLC-Polymer was exposed to H₂S vapor in an enclosed chamber with an outlet.

Applying the CdS-LLC Polymer to Electrodes:

The CdS-LLC polymer film was dried. ITO electrodes were bonded to substrates, and the CdS-LLC polymer film was bonded to the electrodes, such that the film was located between the electrodes, in the manner shown schematically in FIG. 1.

A photoconductive cell, fabricated as described above, was characterised by measuring the current generated by the cell for different applied potentials. Measurements were first taken in the dark and then under UV/visible illumination using a Xe lamp at 15 mW and 50 mW. As shown in FIG. 4, the current was substantially unchanged when the cell was illuminated by 15 mW (compared with no illumination). However, a much larger current was observed when the cell was illuminated with 50 mW.

### REFERENCES

1. S. Karg, W. Reiss, V. Dyakonov and M. Schwoerer, Synth. Met 427,54 (1993).
2. R. N. Marks, J. J. M. Halls, D. D. C. Bradley, R. H. Friend and A. B. Holmes, J. Phys. Condens, Matter, 1, 6 (1994).
3. H. Antoniadis, B. R. Hseih, M. A. Abkowitz, S. A. Jenekhe and M. Stolka, Synth. Met, 265, 62 (1994).
4. G. Yu, C. Zhang and A. J. Heeger, Appl. Phys. Lett, 1540, 64 (1994).
5. J. J. M. Halls, C. A. Walsh, N. C. Greenham, E. A. Marseglia, R. H. Friend, S. C. Moratti and A. B. Holmes, Nature, 498, 376 (1995).
6. J. J. M. Halls, K. Pichler, R. H. Friend, S. C. Moratti and A. B. Holmes, Appl. Phys. Lett, 3120, 68 (1996).
7. R. A. J. Janssen, M. P. T. Christiaans, C. Hare, N. Maertin, N. S. Sariciftci, A. J. Heeger and F. Wudl, J. Chem. Phys., 8840, 103 (1995).
8. N. C. Greenham, Xiaogang Peng and A. P. Alivisatos, Phys, Rev. B, 17628, 54 (1996).
9. J. H. Burroughes, D. D. C. Bradley, A. R. Brown, R. N. Marks, K. Mackay, R. H. Friend, P. L. Burn, and A. B. Holmes, Nature, 539, 347 (1990).

1. A photoelectric cell comprising first and second electrodes, a plurality of nanowires which extend between the electrodes, and a structure disposed between the nanowires.

2. A photoelectric cell according to claim 1, wherein the structure is a columnar structure.

3. A photoelectric cell according to claim 1, wherein the structure comprises tubes each of which are located around a respective nanowire.

4. A photoelectric cell according to claim 3, wherein the tubes extend between the electrodes.

5. A photoelectric cell according to claim 1, wherein the structure comprises organic polymer material.

6. A photoelectric cell according to claim 5, wherein the organic polymer material comprises a cross-linked organic compound.

7. A photoelectric cell according to claim 5, wherein the organic polymer material comprises a polyaromatic compound.

8. A photoelectric cell according to claim 5, wherein the organic polymer material is in a liquid crystalline phase.

9. A photoelectric cell according to claim 8, wherein the phase is a columnar liquid crystalline phase.

10. A photoelectric cell according to claim 1 wherein the nanowires are fabricated from inorganic material.

11. A photoelectric cell according to claim 10, wherein the nanowires are fabricated from inorganic semiconductor material.

12. A photoelectric cell according to claim 11, wherein the inorganic semiconductor material comprises II-IV or II-VI inorganic nanocrystals.

13. A photoelectric cell according to claim 11, wherein the nanocrystals have an ionisation potential that is higher than that of the surrounding inorganic material.

14. A photoelectric cell according to claim 10, wherein the inorganic material comprises transition metal ions.

15. A photoelectric cell according to claim 14, wherein the transition metal ion is selected from the group consisting of cadmium and zinc.

16. A photoelectric cell according to claim 10, wherein the inorganic material comprises an anionic species.

17. A photoelectric cell according to claim 16, wherein the anionic species is selected from the group consisting of sulfur, selenium and tellurium.

18. A photoelectric cell according to claim 1, wherein the nanowires are less than 20 nanometres in diameter.

19. A photoelectric cell according to claim 18, wherein the nanowires are less than 10 nanometres in diameter.

20. A method of fabricating a photoelectric cell comprising the steps: formation of nanowires within a templating agent; and placement of the nanowires between first and second electrodes so that the nanowires extend between the electrodes.

21. A method of fabricating a photoelectric cell according to claim 20, wherein the templating agent is formed by a method comprising the steps: dissolution of a salt of an organic compound in a solvent under conditions suitable for self-organisation of the organic compound to form a gel containing nanotubes; and polymerisation of the nanotubes to form polymeric nanotubes.

22. A method of fabricating a photoelectric cell according to claim 21, wherein the nanotubes are photochemically polymerised.

23. A method of fabricating a photoelectric cell according to claim 21, wherein the nanowires are formed by treatment of the gel with an anion source.

24. A method of fabricating a photoelectric cell according to claim 23, wherein the anion source is selected from the group consisting of hydrogen sulfide, hydrogen selenide and hydrogen telluride.

25. (canceled)

26. (canceled)
